(19) United States
(12) Patent Application Publication
(10) Pub. No.: US 2006/0216890 A1
(43) Pub. Date: Sep. 28, 2006

(54) Method of fabricating flash memory device

(75) Inventor: Myung Kyu Ahn, Icheon-si (KR)

Correspondence Address: MAYER, BROWN, ROWE & MAW LLP, 1909 K STREET, N.W., WASHINGTON, DC, 20006, US

(73) Assignee: Hynix Semiconductor Inc.

(21) Appl. No.: 11/157,835

(22) Filed: Jun. 22, 2005

(30) Foreign Application Priority Data
Mar. 23, 2005 (KR) 2005-24143

(51) Int. Cl. H01L 21/4763

(52) U.S. Cl. 438/257; 438/719; 438/593

(57) ABSTRACT

A method of fabricating a flash memory device, including the steps of (a) forming floating gate patterns on predetermined regions of a semiconductor substrate, (b) forming an interlayer dielectric film on a predetermined region of the semiconductor substrate, including the floating gate patterns, (c) depositing a polysilicon film for a control gate on the entire surface, (d) etching-back the surface of the polysilicon film for the control gate by means of a chemical sputtering process, and (e) forming a tungsten film on the polysilicon film for control gate.

### BACKGROUND

1. Field of the Invention

The present invention relates to a method of fabricating a flash memory device. More specifically, the present invention relates to a method of fabricating a flash memory device, wherein gate etch residue generated at steps of a floating gate and an ONO dielectric film can be prevented.

2. Discussion of Related Art

FIG. 1 is a cross-sectional view of a flash memory device that is fabricated according to conventional technology.

In order to fabricate a gate of a 70 nm class NAND flash memory device, element isolation films 11 having a shallow trench isolation (STI) structure are first formed in field regions of a semiconductor substrate 10 by means of a predetermined process. A plurality of floating gate patterns 12 are formed on the semiconductor substrate 10.

A surface topology has valley regions (I ) and step regions (II) depending upon whether the floating gate patterns 12 exist or not. The valley regions (I ) have a narrow distance between neighboring floating gate patterns 12, and have a valley shape. The step regions (II) have a wide distance between neighboring floating gate patterns 12, and have a step shape.

An ONO film 13 being an interlayer dielectric film and a capping polysilicon film (not shown) are then deposited along the topology of the floating gate patterns 12. The capping polysilicon film and the ONO film 13, which are formed in a peri region and a selective transistor region, are removed by means of a serial process sequence of photolithography, dry etching, and wet etching. An ONO/capping-polysilicon step region (III) is formed at the boundary region where the two layers are removed.

A polysilicon film 14 for a control gate and a tungsten film 15 are then deposited on the entire surface, and a hard mask oxide film 16 is then deposited on the entire surface to a sufficient thickness.

As the polysilicon film 14 and the tungsten film 15 for the control gate are formed along the surface topology defined by the floating gate patterns 12 and the ONO/capping-polysilicon film 13, a thickness of the polysilicon film 14 and the tungsten film 15 for the control gate, which are deposited in the valley regions (I), the floating gate step regions (II), and the ONO/capping-polysilicon step regions (III), is significantly thicker than those deposited in other regions.

Accordingly, when etching the tungsten film 15, the polysilicon film 14 for the control gate, the ONO film 13 and the floating gate patterns 12 in order to form a gate, the tungsten film 15 is under-etched due to a difference in a thickness of the tungsten film 15. This causes residue to remain in the valley regions (I), the floating gate step regions (II), and the ONO/capping-polysilicon step regions (III).

### SUMMARY OF THE INVENTION

Accordingly, the present invention has been made in view of the above problems, and it is an object of the present invention to provide a method of fabricating a flash memory device, wherein generation of gate etch residue can be prevented.

To achieve the above object, according to the present invention, there is provided a method of fabricating a flash memory device, including the steps of (a) forming floating gate patterns on predetermined regions of a semiconductor substrate, (b) forming an interlayer dielectric film on a predetermined region of the semiconductor substrate, including the floating gate patterns, (c) depositing a polysilicon film for a control gate on the entire surface, (d) etching back the surface of the polysilicon film for the control gate by means of a chemical sputtering process, and (e) forming a tungsten film on the polysilicon film for control gate.

In the step (c), the deposition thickness of the polysilicon film for control gate may, in embodiments, be 1000 to 5000 Å.

The chemical sputtering etch process in the step (d) may, in embodiments, be a process using a chemical etch process and a sputtering etch process at the same time.

In embodiments, one of a fluorine-based gas, a chlorine-based gas, HBr and HI can be used as an etchant of the chemical sputtering process in the step (d).

In the step (d), polymer may, in embodiments, be formed at a portion where a surface valley is formed.

In embodiments, O₂ or N₂ gas can be added in order to form the polymer.

The O₂ or N₂ gas may, in embodiments, be added at the ratio of 0 to 90% of the whole gas.

In the step (d), at least one of Ar, BCl3 and Xe can, in embodiments, be added.

The step (d) may, in embodiments, be performed within a plasma etch apparatus.

The plasma etch apparatus can have one of an ICP type, a microwave type and a CCP type.

A temperature of a bottom electrode of the plasma etch apparatus may, in embodiments, be set to 10 to 300° C.

Bias power of the plasma etch apparatus may, in embodiments, be set to 100 to 2000 W.

A frequency of a source that provides the bias power may, in embodiments, be set to 100 Hz to 1 GHz.

A temperature of an inner wall and a top electrode of the plasma etch apparatus may, in embodiments, be set to 50 to 300° C.

### BRIEF DESCRIPTION OF THE DRAWINGS

FIG. 1 is a cross-sectional view of a flash memory device that is fabricated according to the conventional technology; and

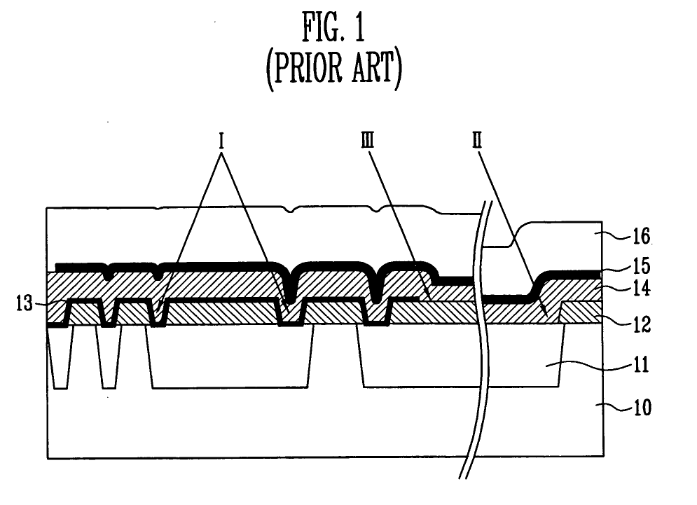

FIGS. 2a and 2b are cross-sectional views illustrating process steps in a method for fabricating a flash memory device according to an embodiment of the present invention.

### DETAILED DESCRIPTION OF PREFERRED EMBODIMENTS

Embodiments according to the present invention will be described with reference to the accompanying drawings. Since these embodiments are provided so that a person of ordinary skill in the art will be able to understand the present invention, the embodiments may be modified in various manners and the scope of the present invention is not limited by the embodiments described herein.

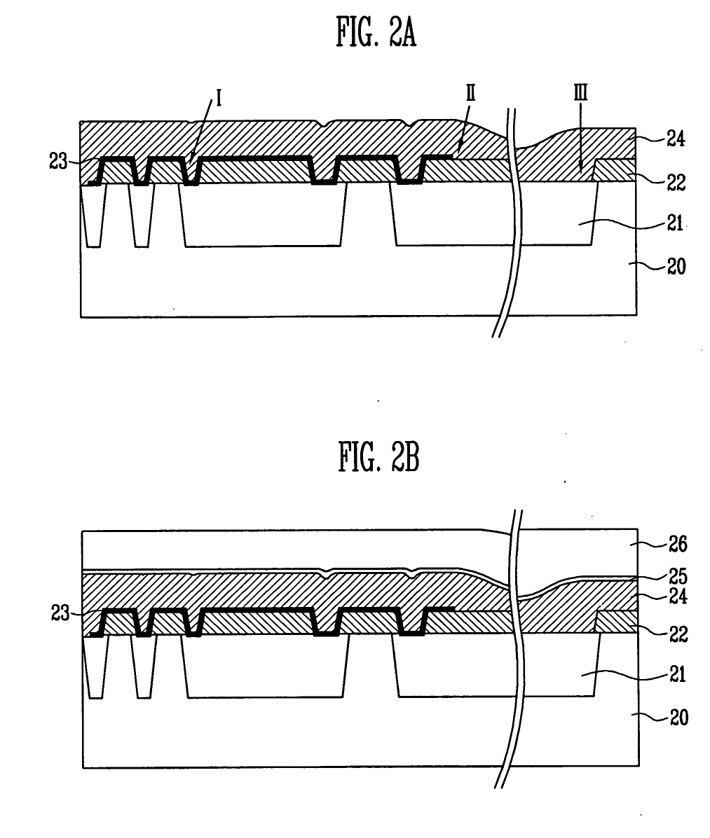

FIGS. 2a and 2b are cross-sectional views illustrating process steps in a method for fabricating a flash memory device according to an embodiment of the present invention.

Referring first to FIG. 2a, element isolation films 21 having a STI structure are formed in field regions of a semiconductor substrate 20. A plurality of floating gate patterns 22 is formed on the semiconductor substrate 20.

A surface topology has valley regions (I) and step regions (II) depending upon whether the floating gate patterns 22 exist or not. The valley regions (I) have a narrow distance between neighboring floating gate patterns 22, and have a valley shape. The step regions (II) have a wide distance between neighboring floating gate patterns 22, and have a step shape.

An ONO film 23 and a capping polysilicon film (not shown) are then formed on the entire surface along the surface topology. The capping polysilicon film (not shown) and the ONO film 23 of a peri region and a selective transistor region are removed by means of a serial process sequence of photolithography, dry etching, and wet etching. As a result of the above process, the surface topology has ONO/capping-polysilicon step regions (III) at the boundary region where the two layers are removed.

A polysilicon film 24 for a control gate is then deposited on the entire surface.

The polysilicon film 24 for the control gate is deposited to a thickness of 1000 to 5000 Å, which is greater than the existing 500 Å films, in order to minimize influence depending upon a lower layer topology.

Thereafter, the surface of the polysilicon film 24 for the control gate is polished by means of a chemical sputtering etch process.

If only the sputtering etch process is used at the time of the surface polishing process, sputtered particles are deposited on inner walls of a chamber. If a process continues, a thick deposition layer is formed on the inner walls of the chamber. Thus, if a drop particle phenomenon in which the deposition layer drops on a wafer on which a process is being performed is generated, there is a problem in that the wafer has to be discarded.

In order to solve this problem, after sputtering etch is completed, a wafer auto plasma cleaning (WAC) process in which the interior of the chamber is automatically cleaned is performed after the wafer is moved out from the chamber. This method however has a problem in that lots of process time is taken.

Meanwhile, if only chemical etching is applied, isotropic etch only is generated. It is thus impossible to realize planarization.

The chemical sputtering etch process used in the present invention is technology in which sputtering etching and chemical etching are applied at the same time. While a planarization effect by sputtering etching is obtained intactly, surface planarization can be realized without a drop particle problem by using characteristics of chemical etching in which byproducts generated due to a reaction of an etchant and a layer that is etched become volatile.

The chemical sputtering etch process can be performed within a plasma etch apparatus of an inductively coupled plasma (ICP) type, a microwave type, a capacitively coupled plasma (CCP) type, and the like.

In order to obtain characteristics in which byproducts formed by sputtering etch become volatile, a temperature of a bottom electrode of the plasma etch apparatus may be set to about 10 to 300° C. In order to reduce the ratio in which the byproducts are re-deposited on an inner wall of a chamber of the plasma etch apparatus, a temperature of the inner wall or a top electrode of the chamber of the plasma etch apparatus may be set to about 50 to 300° C.

Furthermore, in order to obtain sputtering etch characteristics, bias power may be set to about 100 to 2000 W, and a frequency of a source that provides the bias power may be set to about 100 Hz to 1 GHz.

In order to obtain chemical etch characteristics, one of a fluorine-based gas such CF₄, NF₃, SF₆ and CHxFy (x+y=4), a chlorine-based gas such as Cl₂ and CCl₄, and gases such as HBr and Hl gas can be used as an etchant.

Furthermore, in order to improve sputtering etch characteristics, gases such as Ar, BCL₃ and Xe can be added.

In order to improve etching-back characteristics through a reduction of the etch rate of the valley regions (II) by forming polymer, the gases of O₂, N₂, etc. can be added at the ratio of about 0 to 90% of the whole gas.

Thereafter, a tungsten film 25 is deposited on the polysilicon film 24 for the control gate. Since the surface of the polysilicon film 24 for control gate is etched back and become smooth, the tungsten film 25 has almost a constant thickness.

In order to prevent a silicide reaction of the tungsten film 25 and the polysilicon film 24 for the control gate, an anti-silicide film, such as WN and TiN, can be added before the tungsten film 25 is formed.

Next, a hard mask film 26 is formed on the entire surface using an oxide film. After the hard mask film 26 is patterned by means of a serial process sequence of photolithography and dry etching, the tungsten film and polysilicon film 24 for control gate, the capping polysilicon film, the ONO film 23 and the polysilicon film for floating gate 22 are etched using the patterned hard mask film 26 as a mask, thus forming a gate.

Since the deposition thickness of the tungsten film 25 is constant due to surface planarization of the polysilicon film 24 for control gate, an under-etch phenomenon does not occur upon etching for forming the gate.

As described above, the present invention has the following effects.

Firstly, a thickness of a polysilicon film for control gate is increased. A surface of the polysilicon film for control gate is etched back by means of a chemical sputtering etch process using sputtering etch and chemical etch processes at the same time. Accordingly, a tungsten film that is formed subsequently can be formed to a uniform thickness.

Therefore, generation of residue can be prevented from occurring in valley regions and step regions by a floating gate topology and step region by an ONO/capping-polysilicon upon etching of a gate.

Secondly, the etch rate can be improved by applying a sputtering etch process and a chemical etch process at the same time. Therefore, there is an effect in that the throughput can be enhanced.

Although the foregoing description has been made with reference to the above embodiments, it is to be understood that changes and modifications of the present invention may be made by a person of ordinary skill in the art without departing from the spirit and scope of the present invention and appended claims.

What is claimed is:

1. A method of fabricating a flash memory device, the method comprising:
(a) forming floating gate patterns on predetermined regions of a semiconductor substrate;
(b) forming an interlayer dielectric film on a predetermined region of the semiconductor substrate, including the floating gate patterns;
(c) depositing a polysilicon film for a control gate on the entire surface;
(d) etching back the surface of the polysilicon film for the control gate by means of a chemical sputtering process; and
(e) forming a tungsten film on the polysilicon film for the control gate.

2. The method as claimed in claim 1, wherein in the step (c), the deposition thickness of the polysilicon film for the control gate is approximately 1000 to 5000 Å.

3. The method as claimed in claim 1, wherein the chemical sputtering etch process in step (d) is a process using a chemical etch process and a sputtering etch process at the same time.

4. The method as claimed in claim 1, wherein at least one of a fluorine-based gas, a chlorine-based gas, HBr, and Hl is used as an etchant of the chemical sputtering process in step (d).

5. The method as claimed in claim 1, wherein in step (d), a polymer is formed at a portion where a surface valley is formed.

6. The method as claimed in claim 5, wherein O₂ or N₂ gas is added in order to form the polymer.

7. The method as claimed in claim 6, wherein the O₂ or N₂ gas is added at the ratio of approximately 0 to 90% of the whole gas.

8. The method as claimed in claim 1, wherein in step (d), at least one of Ar, BCl₃ and Xe can be added to improve a sputtering etching effect.

9. The method as claimed in claim 1, wherein step (d) is performed within a plasma etch apparatus.

10. The method as claimed in claim 9, wherein the plasma etch apparatus is one of an ICP type, a microwave type and a CCP type.

11. The method as claimed in claim 9, wherein a temperature of a bottom electrode of the plasma etch apparatus is set to approximately 10 to 300° C.

12. The method as claimed in claim 9, wherein bias power of the plasma etch apparatus is set to approximately 100 to 2000 W.

13. The method as claimed in claim 12, wherein a frequency of a source that provides the bias power is set to approximately 100 Hz to 1 GHz.

14. The method as claimed in claim 9, wherein a temperature of an inner wall and a top electrode of the plasma etch apparatus is set to approximately 50 to 300° C.
